(19) United States
(12) Patent Application Publication
(10) Pub. No.: US 2005/0235917 A1
(43) Pub. Date: Oct. 27, 2005

(54) Method and apparatus for monitoring film deposition in a process chamber

(75) Inventors: Jim N. Fordemwalt, Chandler, AZ (US); Eric J. Strang, Chandler, AZ (US); Steven T. Fink, Meza, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 10/514,717

(22) PCT Filed: May 29, 2003
(86) PCT No.: PCT/US03/15392

§ 371 Date: Nov. 23, 2004

Related U.S. Application Data
(60) Provisional application No. 60/383,625, filed on May 29, 2002.

(51) Int. Cl. C23C 16/00

(52) U.S. Cl. 118/723 R; 118/665; 156/345.28

(57) ABSTRACT

An apparatus for monitoring film deposition on a chamber wall in a process chamber. The apparatus includes a surface acoustic wave device provided on the chamber wall. The surface acoustic wave device is actuated to achieve a resonance frequency, and the resonance frequency produced is detected to determine whether a critical thickness of film on the wall of the chamber has been achieved, where an amount of decrease in the resonance frequency is proportional to a thickness of film on the chamber wall. The process chamber is cleaned when the resonance frequency detected falls within a first predetermined range.

### CROSS-REFERENCE TO RELATED APPLICATION

The present invention claims benefit of U.S. Provisional Application No. 60/383,625, filed May 29, 2002.

### BACKGROUND OF THE INVENTION

1. Field of the Invention

The present invention relates to processing chambers, and more particularly, to plasma processing chambers.

2. Discussion of the Background

Plasma processes are widely used in the fabrication of state-of-the-art integrated circuit devices. These processes involve placing the integrated circuit wafer to be processed in a vacuum chamber, removing the air from the chamber, and introducing an appropriate reactant gas or gases at low pressure. An electric field is then applied to the low pressure gas in such a way as to induce an electrical discharge in the gas, commonly known as a plasma. By suitably choosing the chemical composition of the gasses and the voltage, current, and frequency of the electric field, the desired process may be applied to the integrated circuit wafer in the chamber. This process may be, for example, etching of desired circuit patterns into the wafer, or it may be the deposition of desirable thin films over the surface of the integrated circuit wafer.

In order to be competitive in the integrated circuit marketplace, it is necessary that the plasma processes be operated at the lowest possible cost and with the highest possible yield of functional integrated circuits. One of the by-products of the typical plasma processes is the deposition of material commonly known as “polymer” on the walls of the plasma processing chamber. Small amounts of the polymer are desirable, since they “season” the chamber. This seasoning is usually attributed to the fact that a thin coating of the polymer on the chamber walls coating the metal walls provides a chamber environment that is then most consistent during subsequent processing. However, as the processing proceeds, the polymer layer builds up on the walls until it reaches a thickness where bits of the polymer layer begin to flake off and deposit on the surface of the integrated circuit wafer being processed. These pieces of polymer on the surface of the integrated circuit wafer cause catastrophic defects to the devices being processed and result in significantly reduced yields of functional devices.

A solution to the problem of flaking of the polymer layer is to take the plasma processing system out of production, open the processing chamber, and remove the polymer deposits from the plasma chamber walls using one of a number of methods, usually involving wet cleaning. The intervals between wet cleans can, in some cases, be extended by the use of a plasma chamber cleaning process where a suitable gas mixture is introduced into the chamber that will etch the polymer on portions of the chamber wall. In any case, it is usually necessary to season the chamber after cleaning, and before processing of integrated circuit wafers may be resumed.

In any case, the use of wet cleans is necessary periodically. Frequent wet cleaning is undesirable, as it takes the system out of service unnecessarily, and is a premature expense. On the other hand, waiting too long to clean the chamber may be even more expensive, since the yield of viable integrated circuit device may decrease. Since the integrated circuit devices being fabricated may have a sales value of several hundred dollars each, then a yield loss of even a few percent can be intolerably costly.

### SUMMARY OF THE INVENTION

The inventors of the present invention have determined that it would be advantageous to have an apparatus and a method that allows for the precise determination of when a plasma processing system needs to be cleaned. The determination should not be premature, but should be before the polymer build-up begins to flake off and reduce yield. To this end, it is desirable to have a system that is capable of measuring the thickness of the polymer layer built up on the walls of the processing chamber. Then, when the polymer layer has reached a critical thickness, the chamber can be wet cleaned, but not before, thus, avoiding premature cleaning of the chamber. The system can also monitor the polymer thickness after the wet cleaning to determine when the chamber was desirably seasoned, thus expediting the seasoning process.

Accordingly, the present invention advantageously provides an apparatus for monitoring film deposition on a chamber wall in a process chamber. The apparatus includes a surface acoustic wave device provided in close proximity to the chamber wall.

The present invention preferably includes a surface acoustic wave device that has a launcher pair of interdigitated electrodes and a receiver pair of interdigitated electrodes provided on a surface of a piezoelectric substrate. The apparatus preferably includes a voltage supply source configured to supply a first voltage between the launcher pair of interdigitated electrodes, which induces a voltage in the receiver pair of interdigitated electrodes, whereby a surface wave is produced at a resonance frequency of the surface acoustic wave device. The apparatus also preferably includes a processor configured to measure a reference resonance frequency and a second resonance frequency, and compare the second resonance frequency with the reference resonance frequency to determine whether a critical thickness of film on the chamber wall has been achieved.

Furthermore, the present invention advantageously provides a method of monitoring film deposition on a chamber wall within a process chamber that includes the steps of providing a surface acoustic wave device in close proximity to a chamber wall of the process chamber, and actuating the surface acoustic wave device to determine a thickness of film within the process chamber.

The method of the present invention preferably includes actuating the surface acoustic wave device to achieve a resonance frequency, and detecting the resonance frequency. The method further preferably includes cleaning the process chamber when the resonance frequency detected falls within a first predetermined range. The method also preferably includes detecting a resonance frequency of the surface acoustic wave device after the step of cleaning the process chamber, and determining whether the resonance frequency detected after the step of cleaning is within a second predetermined range.

The method of the present invention preferably includes actuating the surface acoustic wave device by applying a launching voltage between a first pair of interdigitated electrodes to generate a surface acoustic wave, developing a voltage between a second pair of interdigitated electrodes, and achieving a reference resonance frequency in the surface acoustic wave device. In the preferred method, the first pair of interdigitated electrodes and the second pair of interdigitated electrodes are provided on a piezoelectric material, and the step of developing a voltage is performed by receiving the surface acoustic wave at the second pair of interdigitated electrodes. The preferred method further includes measuring a second resonance frequency and comparing the second resonance frequency with the reference resonance frequency to determine whether a critical thickness of film on the wall of the chamber has been achieved, where an amount of decrease in the resonance frequency is related to a thickness of film on the wall of the chamber.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is a plan view of a preferred embodiment of a film thickness detector according to the present invention;

FIG. 2 is a cross-section view of the preferred embodiment of a film thickness detector taken along line 11-11 in FIG. 1;

FIG. 3 is a side schematic diagram of a plasma processing system incorporating a film thickness detector according to the present invention;

FIG. 4 is a circuit diagram of a first embodiment of a film thickness detector according to the present invention; and

FIG. 5 is a circuit diagram of a second embodiment of a film thickness detector according to the present invention.

### DETAILED DESCRIPTION OF THE INVENTION

Embodiments of the present invention will be described hereinafter with reference to the accompanying drawings. In the following description, the constituent elements having substantially the same function and arrangement are denoted by the same reference numerals, and repetitive descriptions will be made only when necessary.

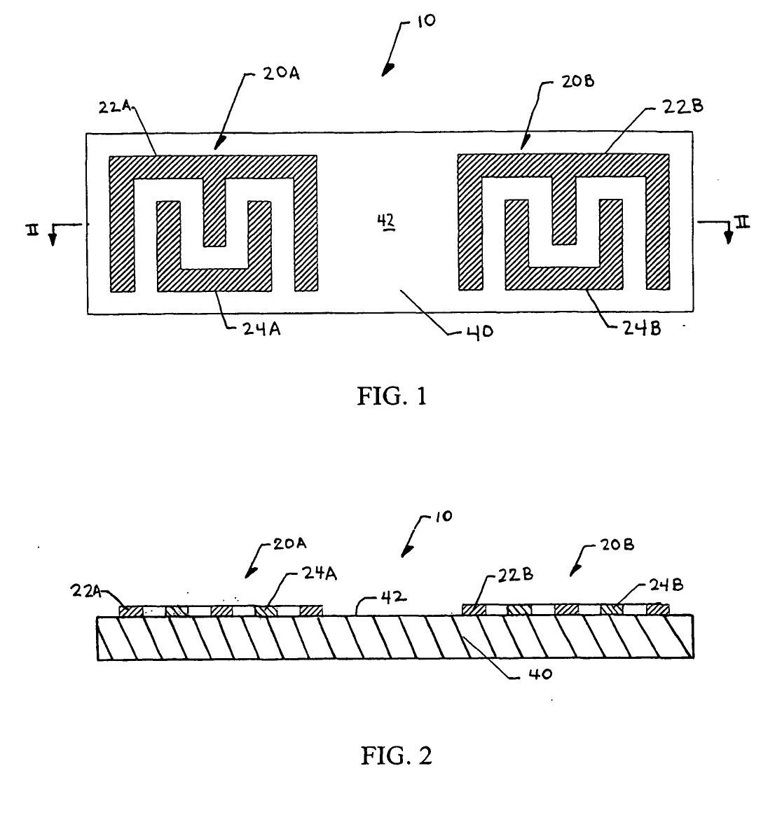

In the exemplary embodiment of FIG. 1, the present invention advantageously utilizes a surface acoustic wave (SAW) device 10 as the detector for the measurement of a film (e.g., a polymer film) thickness on a surface of the plasma processing chamber.

The present invention involves a film thickness detector suitably located in close proximity to one or more of the walls of the plasma processing chamber at locations where the polymer is likely to build up. Locations “in close proximity” as described herein include locations directly on the wall as well as locations within a few centimeters of the wall. The film thickness detector disclosed herein is preferably a SAW device 10. The SAW device 10 preferably includes two pairs of interdigitated electrodes 22A, 24A and 22B, 24B deposited on a surface 42 of a piezoelectric material or substrate 40. The first pair of interdigitated electrodes 22A, 24A is commonly referred to as a launcher 20A, since it “launches” a surface acoustic wave when an appropriate voltage is applied between the first pair of interdigitated electrodes 22A, 24A. The second pair of interdigitated electrodes 22B, 24B, located in close proximity to the first pair, is known as a receiver 20B, since it “receives” the surface acoustic wave that was launched by the launcher 20A. Since the launcher 20A and the receiver 20B are located on the surface 42 of a piezoelectric material 40, then a voltage will be developed between the second pair of interdigitated electrodes 22B, 24B in the presence of the disturbance of a surface acoustic wave. The launcher 20A and the receiver 20B depicted in the figures each include an M-shaped electrode 22A, 22B and a U-shaped electrode 24A, 2413, however, other configurations can be utilized as will be apparent to one of ordinary skill in the art in light of the present disclosure.

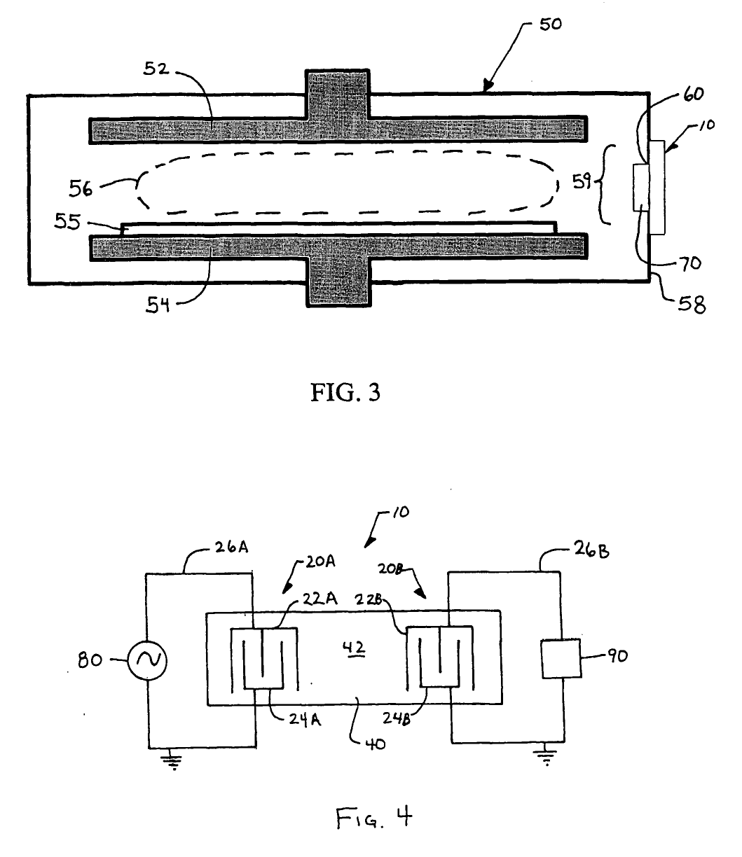

If a layer of material is deposited on the surface of the SAW device 10, the mass of the material will “load” the device 10, and the resonance frequency will be lowered. The amount of lowering of the resonance frequency is related to the mass of material. Ultimately, however, if the mass of material is too great, the surface acoustic wave will be damped out, and the oscillation will cease, thus placing an upper limit on the thickness of material that can be measured by the SAW device 10. Because of this limitation, it may be desirable to place a partially opaque screen 70 (FIG. 3) between the SAW device 10 and plasma within a plasma chamber 50, as will be described below, in order to reduce the quantity of material deposited on the SAW device 10 during normal operation of the plasma chamber. For example, screen 70 can comprise a dielectric material.

The present invention advantageously provides an apparatus for monitoring film deposition on a chamber wall 58 in a process chamber 50, as shown in FIG. 3. The apparatus includes a SAW device 10 provided in close proximity to the chamber wall 58. The SAW device 10 may be oriented in any one of several orientations (e.g., with electrodes facing a process wall or with electrodes facing the interior of the chamber and the electrodes 27A and 27B facing up, down, left or right).

As shown in FIG. 4, the SAW device 10 includes a voltage supply source 80 configured to supply a first voltage via circuit 26A to the launcher 20A between the launcher pair of interdigitated electrodes 22A, 24A. The voltage supplied between the launcher pair of interdigitated electrodes 22A, 24A launches an acoustical wave which is transmitted along the piezoelectric substrate 40 and induces a voltage in the receiver pair of interdigitated electrodes 22B, 24B and along circuit 26B, whereby an oscillation is produced at a resonance frequency of the SAW device 10. The SAW device 10 also includes a processor 90 configured to measure a resonance frequency in the SAW device to determine whether a critical thickness of film on the chamber wall has been achieved, as will be described in more detail below.

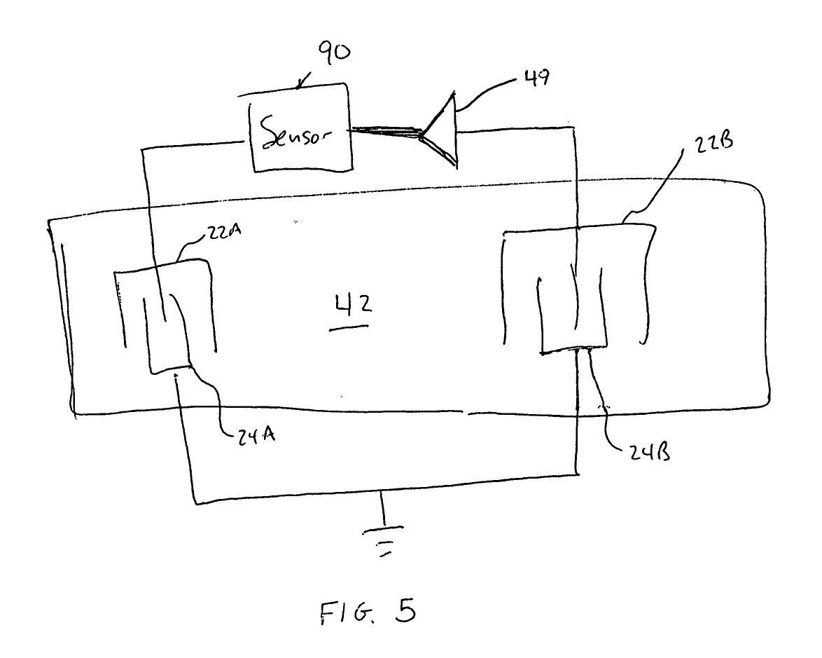

As shown in FIG. 5, if the output of the receiver 20B is suitably amplified (e.g., by amplifier 49) and fed back into the launcher 20A, the surface acoustic wave device 10 will oscillate at its resonance frequency. By applying the output of the amplifier to a frequency sensor 90, the amount of buildup can be measured.

The process chamber 50 depicted in FIG. 3 generally includes an upper electrode 52 positioned opposite to a lower electrode 54. A wafer 55 is mounted on the lower electrode 54 for processing, and then a plasma is generated within a plasma region 56 using known methods. The SAW device 10 is provided at a monitoring location 59 on the chamber wall 58 adjacent to the plasma region 56 within the process chamber 50. The SAW device 10 can be mounted on an inner surface of the chamber wall 58, or a port 60 can be formed in the chamber wall 58 and the SAW device 10 can be mounted within the port 60. In certain instances, as discussed above, it may be desirable to place a screen 70, which is preferably partially opaque, on the SAW device 10. The screen 70 can be provided between the SAW device 10 and the chamber wall 58, as generally depicted in FIG. 3. The screen 70 is provided between the SAW device 10 and a chamber environment in order to reduce the quantity of material deposited on the SAW device 10 during normal operation of the plasma chamber 50.

The present invention advantageously provides a method of monitoring film deposition on a chamber wall within a process chamber that generally includes actuating the SAW device 10 to determine a thickness of film within the process chamber 50. The method includes actuating the SAW device 10 to achieve a resonance frequency, and detecting the resonance frequency. The SAW device 10 is actuated by applying a launching voltage between the first pair of interdigitated electrodes 22A, 24A to generate a surface acoustic wave, which induces a voltage between the second pair of interdigitated electrodes 22B, 24B in the presence of the disturbance of a surface acoustic wave. If the output of the receiver 20B is suitably amplified by the surface acoustic wave from the launcher 20A and fed back into the launcher 20A, the surface acoustic wave device 10 will oscillate at its resonance frequency. When the SAW device 10 is in a clean state, without any plasma material deposited thereon, the SAW device 10 will oscillate at a reference resonance frequency, which can be used as a reference to determine whether the SAW device 10 has material deposited thereon, since the resonance frequency of the SAW device 10 is dampened by a plasma layer provided on the SAW device 10.

The present invention preferably includes a measuring and monitoring device 90 for measuring the resonance frequency of the SAW device 10 at various intervals or on a continuous basis in order to determine whether a cleaning process is necessary. The measuring and monitoring device 90 can generally include a device for measuring the frequency of the voltage in circuit 26B, such as a frequency sensor, a frequency-to-voltage converter, frequency counter, phase lockloop, or other similar device. The device 90 is also configured to compare the frequency sensed to a predetermined frequency or range of frequencies, which can be determined experimentally, for example. The amount of decrease in the resonance frequency is proportional to a thickness of film on the SAW device 10, which, due to the location of the SAW device 10 at the monitoring location 59 on the chamber wall 58 adjacent to the plasma region 56, is generally equivalent to the maximum thickness of film on the wall 58 of the chamber 50. Accordingly, the method of the present invention includes the step of cleaning the process chamber 50 when the resonance frequency detected by the device 90 dampens and falls within a predetermined range or dampens to a level below a predetermined value that represents that a critical thickness of film on the wall 58 of the chamber 50 has been achieved. The decrease in resonance frequency can be effected by the deposition of film on the launcher 20A, the receiver 20B, or both.

Once the device 90 has determined that a cleaning process is required, the chamber 50 is disassembled (if necessary), cleaned, and reassembled. Then the SAW device 10 can be activated to generate a resonance frequency and the device 90 can be used to measure the frequency and determine whether the SAW device 10 and chamber 50 have been cleaned to a sufficient degree, for example, by determining whether the measured resonance frequency is within a second predetermined range, or is greater than or less than a second predetermined value. If the measured resonance frequency is not within the second predetermined range or is less than the second predetermined value, then an additional cleaning procedure should be performed prior to further use of the processing chamber 50. It may be desirable to set the second predetermined range or the second predetermined value at a level that corresponds to a level at which the SAW device 10 is properly “seasoned,” which will be different from the reference resonance frequency of a completely clean SAW device.

The SAW device 10 of the present invention is sensitive to being overloaded, and any abrasion of the surface of the SAW device 10 either during cleaning or as the result of inadvertent contact with the surface can destroy the device. Therefore, care should be taken to ensure the continued operation of the SAW device 10. The SAW device 10 can be damaged by the wet cleaning operation, therefore the ability to replace the SAW element easily as part of the wet cleaning operation is preferable. Also, since the SAW device 10 depends on self-oscillation and must operate in an environment with high levels of RF energy, extreme shielding of the device may be necessary to prevent spurious operation resulting from the interaction with the RF power used to excite the plasma.

The primary advantage of the present invention is the ability to determine the optimum time to wet clean the plasma processing chamber, and to determine when the chamber has been properly seasoned after wet cleaning.

It should be noted that the exemplary embodiments depicted and described herein set forth the preferred embodiments of the present invention, and are not meant to limit the scope of the claims hereto in any way. Numerous modifications and variations of the present invention are possible in light of the above teachings. It is therefore to be understood that, within the scope of the appended claims, the invention may be practiced otherwise than as specifically described herein.

1. An apparatus for monitoring film deposition on a chamber wall in a process chamber, said apparatus comprising:
a surface acoustic wave device adapted to be provided in close proximity to the chamber wall.

2. The apparatus according to claim 1, wherein said surface acoustic wave device comprises a launcher pair of interdigitated electrodes and a receiver pair of interdigitated electrodes.

3. The apparatus according to claim 2, further comprising a piezoelectric substrate, wherein said launcher pair of interdigitated electrodes and said receiver pair of interdigitated electrodes are provided on a surface of said piezoelectric substrate.

4. The apparatus according to claim 3, further comprising a voltage supply source configured to supply a first voltage between said launcher pair of interdigitated electrodes, which induces a voltage in said receiver pair of interdigitated electrodes, whereby an oscillation is produced at a resonance frequency of said surface acoustic wave device.

5. The apparatus according to claim 4, further comprising a processor configured to measure a reference resonance frequency and a second resonance frequency, and compare the second resonance frequency with the reference resonance frequency to determine whether a critical thickness of film on the chamber wall has been achieved.

6. The apparatus according to claim 1, further comprising a partially opaque screen provided on said surface acoustic wave device, said partially opaque screen being adapted to be provided between said surface acoustic wave device and the process chamber.

7. An apparatus for monitoring film deposition on a chamber wall in a process chamber, said apparatus comprising:
means for detecting a film thickness adapted to be provided in close proximity to the chamber wall.

8. The apparatus according to claim 7, wherein said means for detecting a film thickness comprises a surface acoustic wave device having a launcher pair of interdigitated electrodes and a receiver pair of interdigitated electrodes.

9. The apparatus according to claim 8, further comprising a piezoelectric substrate, wherein said launcher pair of interdigitated electrodes and said receiver pair of interdigitated electrodes are provided on a surface of said piezoelectric substrate.

10. The apparatus according to claim 9, further comprising a voltage supply source configured to supply a first voltage between said launcher pair of interdigitated electrodes, which induces a voltage in said receiver pair of interdigitated electrodes, whereby an oscillation is produced at a resonance frequency of said surface acoustic wave device.

11. The apparatus according to claim 10, further comprising a processor configured to measure a reference resonance frequency and a second resonance frequency, and compare the second resonance frequency with the reference resonance frequency to determine whether a critical thickness of film on the chamber wall has been achieved.

12. The apparatus according to claim 7, further comprising a partially opaque screen provided on said means for detecting a film thickness, said partially opaque screen being adapted to be provided between said means for detecting a film thickness and the process chamber.

13. A process chamber comprising:
a chamber wall; and
a surface acoustic wave device provided in close proximity to the chamber wall.

14. The process chamber according to claim 13, wherein said surface acoustic wave device comprises a launcher pair of interdigitated electrodes and a receiver pair of interdigitated electrodes.

15. The process chamber according to claim 14, further comprising a piezoelectric substrate provided on said chamber wall, wherein said launcher pair of interdigitated electrodes and said receiver pair of interdigitated electrodes are provided on a surface of said piezoelectric substrate.

16. The process chamber according to claim 15, further comprising a voltage supply source configured to supply a first voltage between said launcher pair of interdigitated electrodes, which induces a voltage in said receiver pair of interdigitated electrodes, whereby an oscillation is produced at a resonance frequency of said surface acoustic wave device.

17. The process chamber according to claim 16, further comprising a processor configured to measure a reference resonance frequency and a second resonance frequency, and compare the second resonance frequency with the reference resonance frequency to determine whether a critical thickness of film on said chamber wall has been achieved.

18. The process chamber according to claim 13, further comprising a partially opaque screen provided on said surface acoustic wave device, said partially opaque screen being provided between said surface acoustic wave device and said chamber wall.

19. The process chamber according to claim 13, further comprising a partially opaque screen provided between said surface acoustic wave device and a chamber environment.

20. The process chamber according to claim 13, wherein said chamber wall has a port, said surface acoustic wave device being provided within said port.

21. The process chamber according to claim 13, wherein said surface acoustic wave device is provided at a monitoring location adjacent to a plasma region within said process chamber.

22. A process chamber comprising:
a chamber wall; and
means for detecting a film thickness, said means for detecting being provided in close proximity to the chamber wall.

23. The process chamber according to claim 22, wherein said means for detecting a film thickness comprises a surface acoustic wave device having a launcher pair of interdigitated electrodes and a receiver pair of interdigitated electrodes.

24. The process chamber according to claim 23, further comprising a piezoelectric substrate, wherein said launcher pair of interdigitated electrodes and said receiver pair of interdigitated electrodes are provided on a surface of said piezoelectric substrate.

25. The process chamber according to claim 24, further comprising a voltage supply source configured to supply a first voltage between said launcher pair of interdigitated electrodes, which induces a voltage in said receiver pair of interdigitated electrodes, whereby an oscillation is produced at a resonance frequency of said surface acoustic wave device.

26. The process chamber according to claim 25, further comprising a processor configured to measure a reference resonance frequency and a second resonance frequency, and compare the second resonance frequency with the reference resonance frequency to determine whether a critical thickness of film on said chamber wall has been achieved.

27. The process chamber according to claim 22, further comprising a partially opaque screen provided on said means for detecting a film thickness, said partially opaque screen being provided between said means for detecting a film thickness and said chamber wall.

28. The process chamber according to claim 22, further comprising a partially opaque screen provided between said means for detecting a film thickness and a chamber environment.

29. The process chamber according to claim 22, wherein said chamber wall has a port, said means for detecting a film thickness being provided within said port.

30. The process chamber according to claim 22, wherein said means for detecting a film thickness is provided at a monitoring location adjacent to a plasma region within said process chamber.

31. A method of monitoring film deposition on a chamber wall within a process chamber, said method comprising the steps of:
providing a surface acoustic wave device in close proximity to the chamber wall of the process chamber; and
actuating the surface acoustic wave device to determine a thickness of film within the process chamber.

32. The method according to claim 31, further comprising the steps of providing a port in the chamber wall, and providing the surface acoustic wave device within the port.

33. The method according to claim 32, further comprising the step of providing a partially opaque screen within the port, wherein the partially opaque screen is provided between the surface acoustic wave device and a chamber environment.

34. The method according to claim 31, further comprising the step of providing a partially opaque screen between the surface acoustic wave device and a chamber environment.

35. The method according to claim 31, wherein the surface acoustic wave device is provided at a monitoring location adjacent to a plasma region within the process chamber.

36. The method according to claim 31, wherein the resonance frequency is dampened by a plasma layer provided on the surface acoustic wave device.

37. The method according to claim 31, wherein the step of actuating the surface acoustic wave device further comprises the steps of actuating the surface acoustic wave device to achieve a resonance frequency, and detecting the resonance frequency.

38. The method according to claim 37, further comprising the step of cleaning the process chamber when the resonance frequency detected falls within a first predetermined range.

39. The method according to claim 38, further comprising the step of detecting a resonance frequency of the surface acoustic wave device after the step of cleaning the process chamber.

40. The method according to claim 39, further comprising the step of determining whether the resonance frequency detected after the step of cleaning is within a second predetermined range.

41. The method according to claim 39, further comprising the step of determining whether the resonance frequency detected after the step of cleaning is greater than a predetermined value.

42. The method according to claim 39, further comprising the step of determining whether the resonance frequency detected after the step of cleaning is less than a predetermined value.

43. The method according to claim 31, wherein the step of actuating the surface acoustic wave device comprises the steps of:
applying a launching voltage between a first pair of interdigitated electrodes to generate a surface acoustic wave;
developing a voltage between a second pair of interdigitated electrodes, wherein the first pair of interdigitated electrodes and the second pair of interdigitated electrodes are provided on a piezoelectric material, wherein the step of developing a voltage is performed by receiving the surface acoustic wave at the second pair of interdigitated electrodes; and
achieving a reference resonance frequency in the surface acoustic wave device.

44. The method according to claim 43, further comprising the step of measuring a second resonance frequency and comparing the second resonance frequency with the reference resonance frequency to determine whether a critical thickness of film on the chamber wall has been achieved, wherein an amount of decrease in the resonance frequency is proportional to a thickness of film on the chamber wall.
